(19) United States
(12) Patent Application Publication
(10) Pub. No.: US 2017/0212181 A1
(43) Pub. Date: Jul. 27, 2017

(54) REDUCED INSTRUCTION SET CONTROLLER FOR DIAMOND NITROGEN VACANCY SENSOR

(71) Applicant: Lockheed Martin Corporation, Bethesda, MD (US)

(72) Inventors: David N. Coar, Cherry Hill, NJ (US); Jon C. Russo, Cherry Hill, NJ (US); Boris Shishkin, Philadelphia, PA (US)

(73) Assignee: Lockheed Martin Corporation, Bethesda, MD (US)

(21) Appl. No.: 15/003,336

(22) Filed: Jan. 21, 2016

(51) Int. Cl. G01R 33/032; G05B 19/04

(52) U.S. Cl. CPC G01R 33/032; G05B 19/04; G05B 2219/25126

(57) ABSTRACT

Systems, controllers, and configurations are disclosed for providing precisely timed laser actuation, RF waveform control, and synchronous acquisition of fluorescence information from magnetometry components, such as a DNV sensor. A controller for a DNV sensor may include a RF waveform generator for generating a RF waveform for a RF signal for a DNV sensor and a digital control for controlling a laser for the DNV sensor. The RF waveform generator and the digital control may be formed in a single chip, such as an FPGA or ASIC.

### FIELD

The subject technology generally relates to magnetometry, and more particularly, to synchronous control, radio-frequency (RF) synthesis, and fluorescence acquisition processor for diamond nitrogen-vacancy (DNV).

### BACKGROUND

Atomic-sized nitrogen-vacancy (NV) centers in diamond lattices have been shown to have excellent sensitivity for magnetic field measurement and enable fabrication of small magnetic sensors that can readily replace existing-technology (e.g., Hall-effect) systems and devices. The diamond NV (DNV) sensors are maintained in room temperature and atmospheric pressure and can be even used in liquid environments. A green optical source (e.g., a laser or a micro-LED) can optically excite NV centers of the DNV sensor and cause emission of fluorescence radiation (e.g., red light) under off-resonant optical excitation. A magnetic field generated, for example, by a microwave coil can probe degenerate triplet spin states (e.g., with mₛ=−1, 0, +1) of the NV centers to split proportional to an external magnetic field projected along the NV axis, resulting in two spin resonance frequencies. The distance between the two spin resonance frequencies is a measure of the strength of the external magnetic field.

A photo detector can measure the fluorescence (red light) emitted by the optically excited NV centers and a DNV system is used to control the laser and microwave timings and perform the data acquisition.

### SUMMARY

Various aspects of the subject technology provide methods and systems for providing precisely timed laser actuation, RF waveform control, and synchronous acquisition of fluorescence information from a DNV magnetometer. In the following description, reference is made to the accompanying attachments that form a part thereof, and in which are shown by way of illustration, specific embodiments in which the subject technology may be practiced. It is to be understood that other embodiments may be utilized and changes may be made without departing from the scope of the subject technology.

One implementation relates to a controller for a DNV sensor that includes a RF waveform generator for generating a RF waveform for a RF signal for a DNV sensor and a digital control for controlling a laser for the DNV sensor. The RF waveform generator and the digital control are formed in a single chip.

In some implementations, the single chip is a field-programmable gate array or an application specific integrated circuit. In some implementations, the RF waveform generator and the digital control operate on single-cycle instructions or two-cycle instructions. In some implementations, the RF waveform generator and the digital control operate on single-cycle instructions of a reduced instruction set. In some implementations, the RF waveform generator includes a coordinate rotation digital computer. In some implementations, the RF waveform generator utilizes a frequency base and a frequency increment to generate the RF waveform. In some implementations, the RF waveform generated by the RF waveform generator is processed through an upconverter to generate the RF signal. In some implementations, the digital control includes RF gating. In some implementations, the digital control includes general inputs or outputs. In some implementations, the digital control is configured to control the generation of the RF waveform. In some implementations, the digital control is configured to control optic pulsing of the laser. In some implementations, the single chip is configured to be integrated into one of a geo-location system, an anomaly detection system, a distributed measure point system, a communication system, an unmanned air vehicle, a micro unmanned air vehicle, a missile, an unmanned sea vehicle, an unmanned underground vehicle, or a satellite.

Another implementation relates to a controller for a DNV sensor that includes a RF waveform generator for generating a RF waveform for a RF signal for a DNV sensor, a digital control for controlling a laser for the DNV sensor, and an acquisition processor. The RF waveform generator, the digital control, and the acquisition processor are formed in a single chip.

In some implementations, the single chip is a field-programmable gate array or an application specific integrated circuit. In some implementations, the RF waveform generator, the digital control, and the acquisition processor operate on single-cycle instructions or two-cycle instructions. In some implementations, the RF waveform generator, the digital control, and the acquisition processor operate on single-cycle instructions of a reduced instruction set. In some implementations, the acquisition processor preprocesses data received from a photo detector of the DNV sensor. In some implementations, the acquisition processor decimates the data received from the photo detector of the DNV sensor. In some implementations, the single chip is configured to be integrated into one of a geo-location system, an anomaly detection system, a distributed measure point system, a communication system, an unmanned air vehicle, a micro unmanned air vehicle, a missile, an unmanned sea vehicle, an unmanned underground vehicle, or a satellite.

Yet another implementation relates to a controller for a DNV sensor that includes a RF waveform generator for generating a RF waveform for a RF signal for a DNV sensor, a digital control for controlling a laser for the DNV sensor, an acquisition processor, a host interface for interfacing with an external system, a program counter, a program memory, and a jump control. The the RF waveform generator, the digital control, the acquisition processor, the host interface, the program counter, the program memory, and the jump control are formed in a single chip

In some implementations, the single chip is a field-programmable gate array or an application specific integrated circuit. In some implementations, the RF waveform generator, the digital control, and the acquisition processor operate on single-cycle instructions or two-cycle instructions. In some implementations, the RF waveform generator, the digital control, and the acquisition processor operate on single-cycle instructions of a reduced instruction set. In some implementations, the single chip is configured to be integrated into one of a geo-location system, an anomaly detection system, a distributed measure point system, a communication system, an unmanned air vehicle, a micro unmanned air vehicle, a missile, an unmanned sea vehicle, an unmanned underground vehicle, or a satellite.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 is a block diagram of an overview of a single-cycle synthesis, control, and acquisition system for a diamond nitrogen vacancy sensor;

FIG. 2 is a block circuit diagram of the single-cycle control, synthesis, and acquisition processor for a diamond nitrogen vacancy sensor of FIG. 1;

FIG. 3A is a block circuit diagram of the host interface of FIG. 2;

FIG. 3B is a block circuit diagram of the program counter of FIG. 2;

FIG. 3C is a block circuit diagram of the program memory of FIG. 2;

FIG. 3D is a block circuit diagram of a first portion of the jump control with delay of FIG. 2;

FIG. 3E is a block circuit diagram of a second portion of the jump control FIG. 2;

FIG. 3F is a block circuit diagram of the RF waveform generator of FIG. 2;

FIG. 3G is a block circuit diagram of the digital control of FIG. 2;

FIG. 3H is a block circuit diagram of the acquisition processor of FIG. 2; and

FIG. 4 is a block diagram depicting a general architecture for a computer system that may be employed to interact various elements of the systems and methods described and illustrated herein.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

Following below are more detailed descriptions of various concepts related to, and implementations of, methods, apparatuses, and systems for providing synchronous control of multiple RF signals and digital output signals for magnetometry, such as for a diamond nitrogen vacancy (DNV) sensor. The subject technology can provide the synchronous control with controlled, single-cycle timing requirements for a flexible and sensitive DNV magnetometry. In some implementations, the disclosed system includes a reduced instruction set (RISC) processor that is coupled to a configurable signal synthesizer. The configurable signal synthesizer may be configured to perform single-cycle commands for frequency shifts, digital outputs, and initial synchronous preprocessing of received data such that the digital control, acquisition, and waveform generation may be performed on the same clock cycle for synchronization. The specially designed single-cycle operations of the subject technology may provide more precise and deterministic timing for digital control, acquisition, and waveform generation. In some implementations, the RF waveform generation and digital control outputs are coordinated in configurable patterns that can range from simple sequences to complex adaptive control patterns.

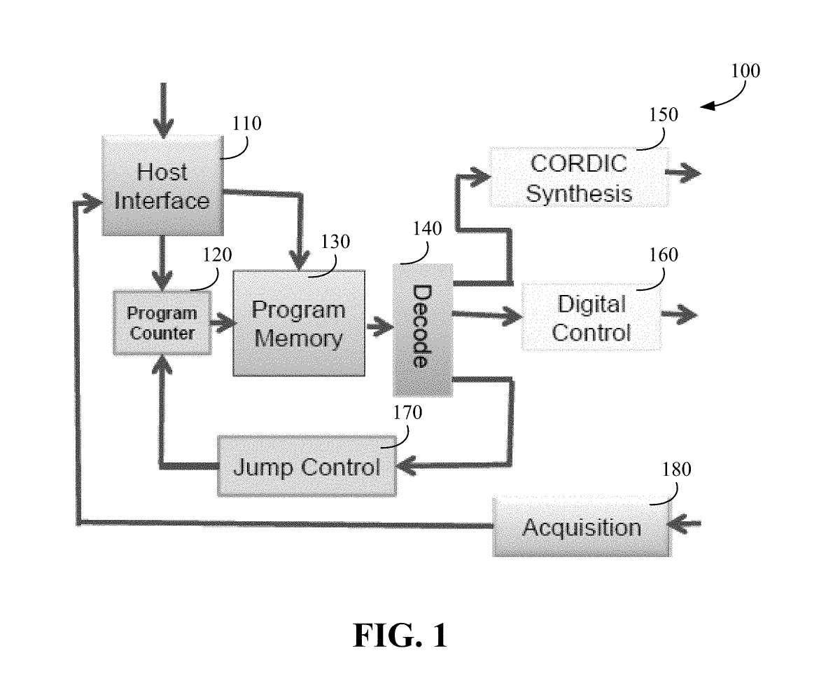

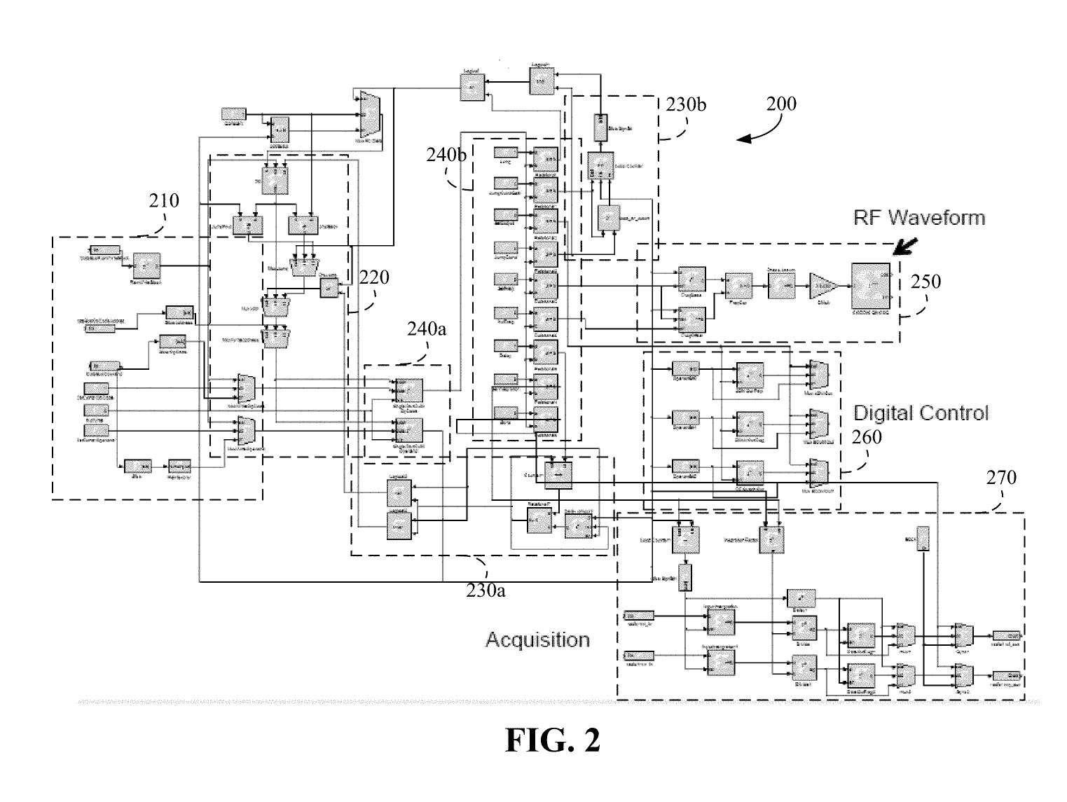

FIG. 1 is a block diagram depicting an overview of an implementation of a single-cycle synthesis, control, and acquisition system 100. The system 100 is configured to control multiple RF signals and digital output signals for magnetometry, such as for a diamond nitrogen vacancy (DNV) sensor. In some implementations, the system 100 may be implemented as a field-programmable gate array (FPGA) or may be implemented as an application specific integrated circuit (ASIC). The system 100 is implemented as a single single-cycle integrated circuit for RF waveform synthesis, digital control, and acquisition. A more detailed implementation of the single-cycle synthesis, control, and acquisition system is shown as the system 200 in FIG. 2.

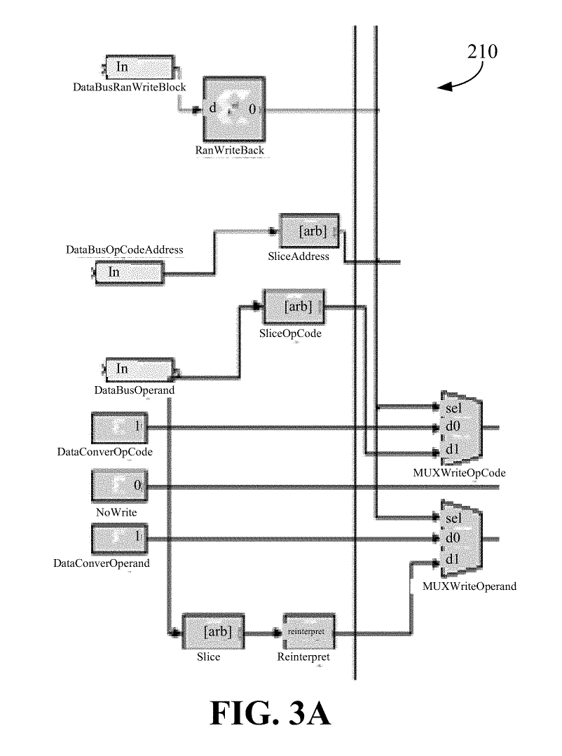

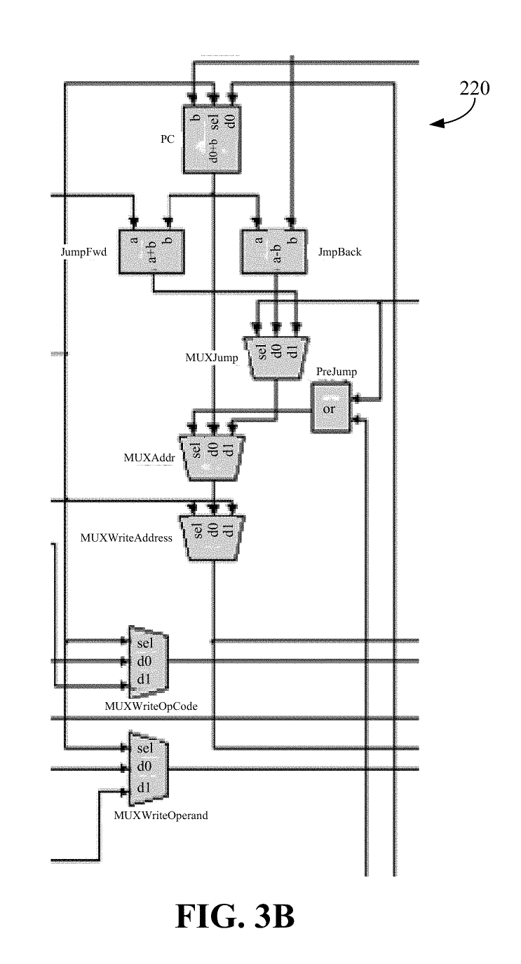

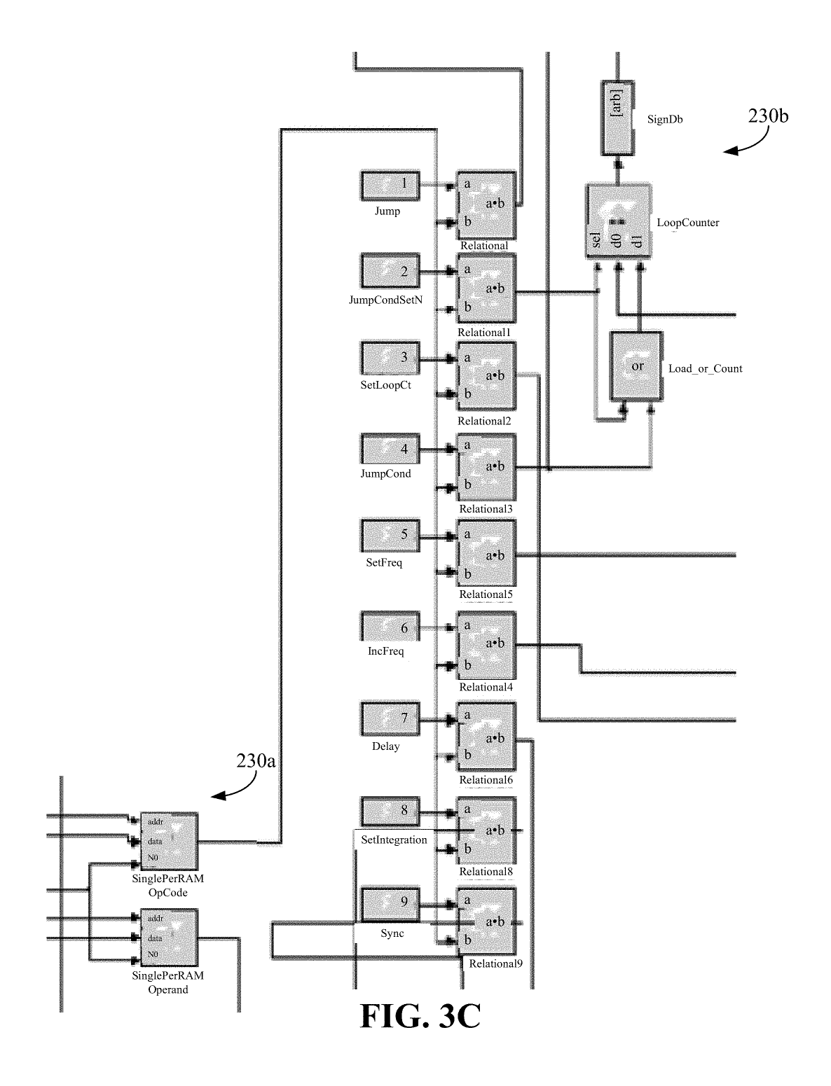

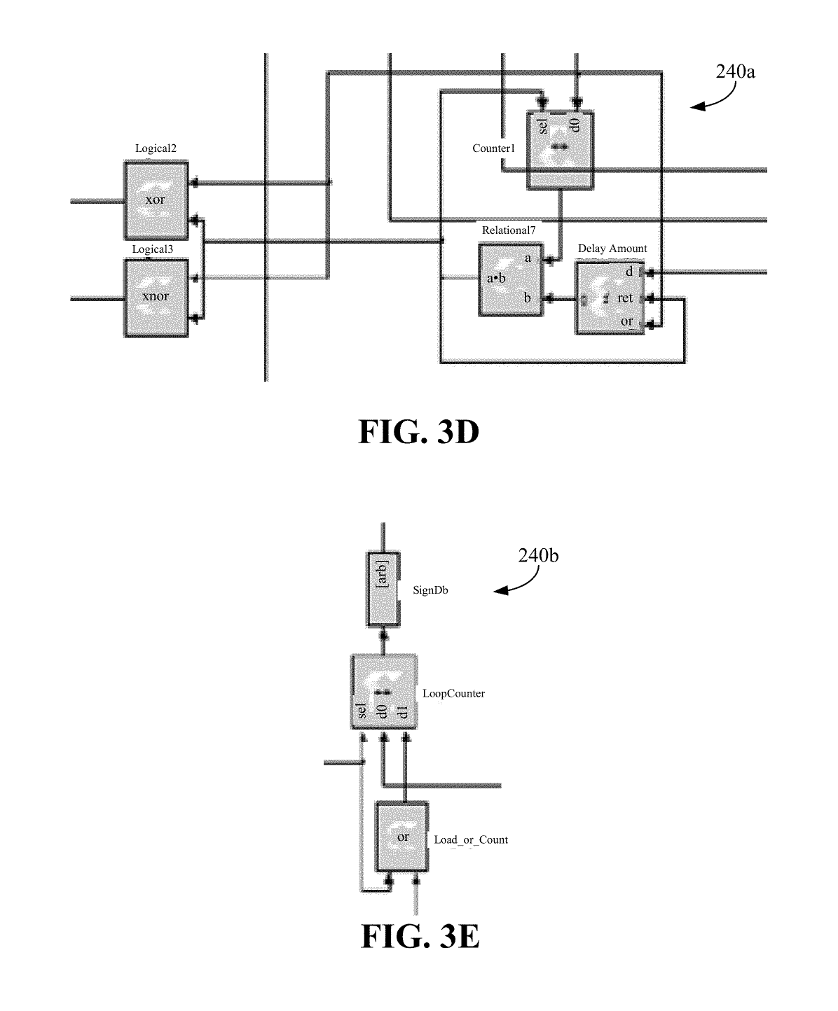

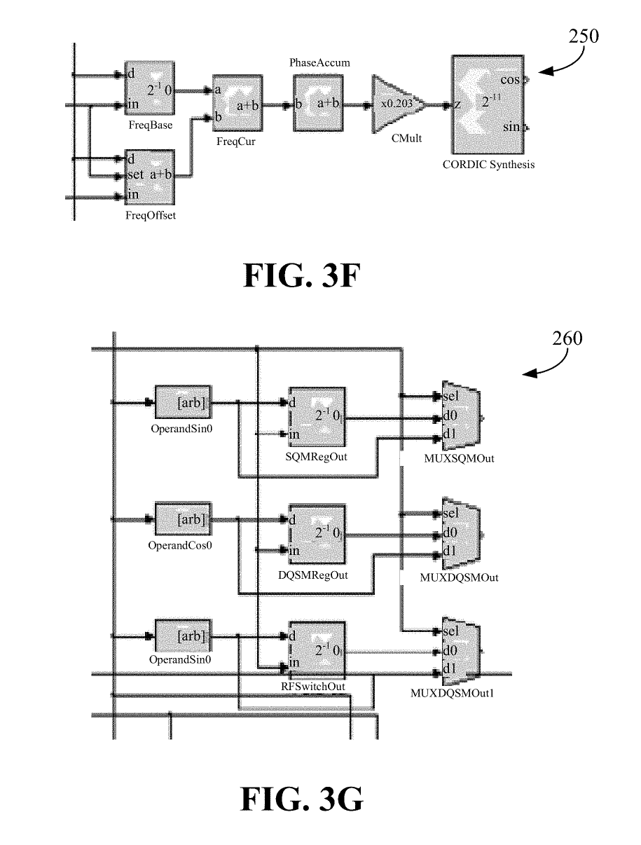

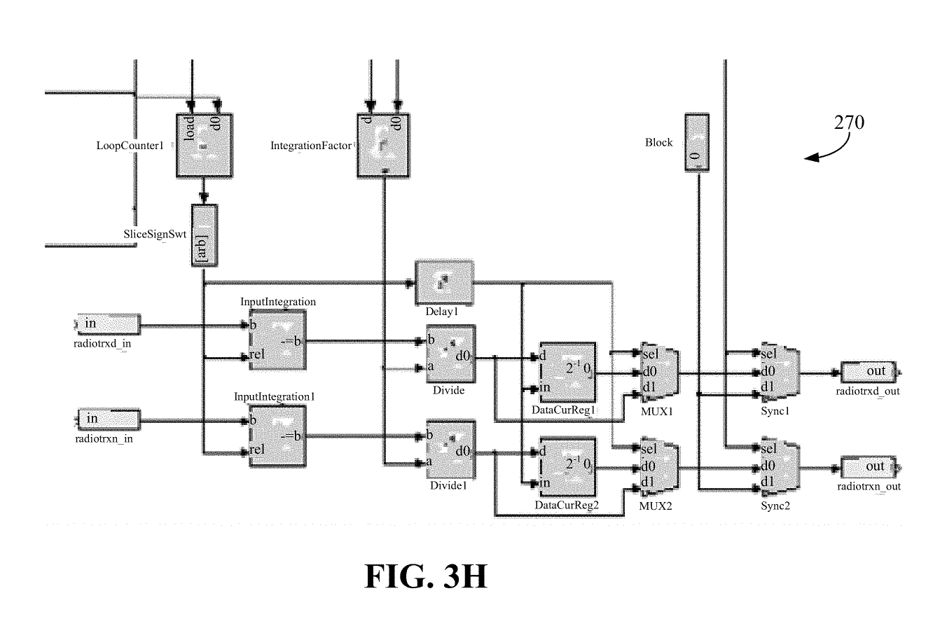

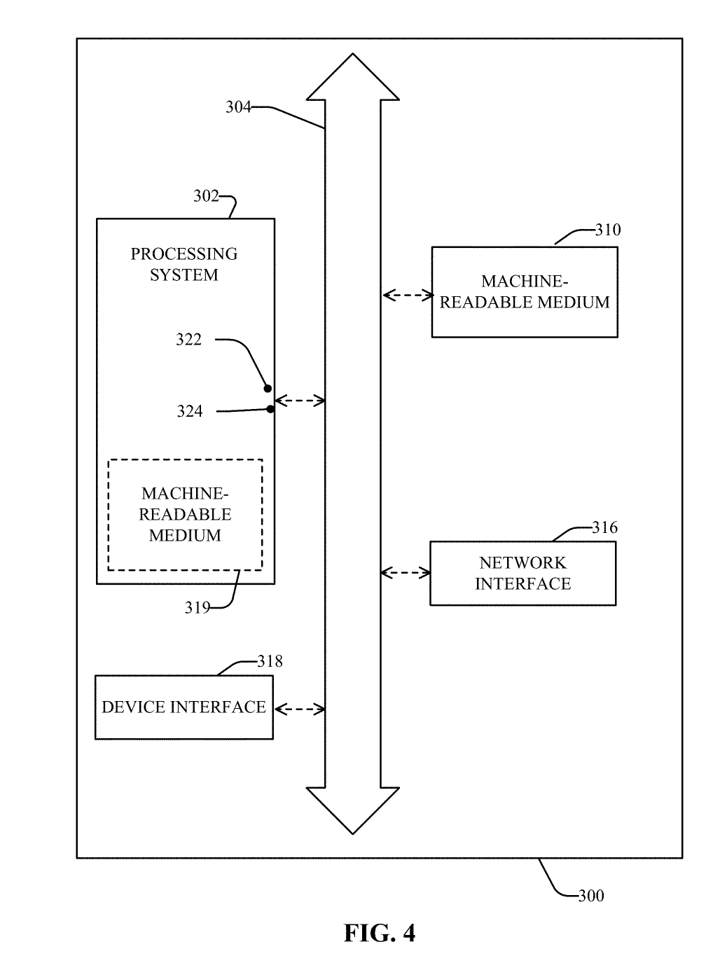

The system 100 includes a host interface 110 that receives DNV sensing information from an external system, such as a data processing or acquisition system (not shown), and is communicatively coupled to a program counter 120, a program memory 130, and an acquisition processor 180. The host interface 110 may be coupled to a data processing system, such as system 300 of FIG. 3, that can communicate with the system 100 via the host interface 110. Thus, the data processing system can output instructions, such as control instructions from the reduced instruction set, to the system 100 via the host interface 110 for the program memory 130. The data acquisition system can also receive output from the acquisition processor 180 via the host interface 110, such as pulse processed data from a DNV sensor. Thus, the host interface 110 provides communication between the components of the system 100 and an external system. A more detailed depiction of the host interface 110 is shown as host interface 210 in FIGS. 2 and 3A. The host interface 110 is communicatively coupled to the program counter 120, which is in communication with the program memory 130 and the jump control 170. A more detailed implementation of the program counter 120 is shown as program counter 220 in FIGS. 2 and 3B. A more detailed implementation of the program memory 130 is shown as program memory 230a, 230b in FIGS. 2 and 3C. A more detailed implementation of the jump control 170 is shown as jump control with delay 240a and the jump control 240b in FIGS. 2 and 3D-E. The program memory 130 provides outputs through a decoder 140 to a RF waveform generator of the CORDIC (COordinate Rotation DIgital Computer) synthesis 150 for generating the RF waveform to be applied, the digital control 160 for controlling a laser on/off timing, and a jump control 170. The jump control 170 provides feedback to the program counter 120.

The CORDIC synthesis 150 provides digital up or down conversion and can have a run-time configurable base frequency and increment for the RF waveform generation. The RF waveform generator of the CORDIC synthesis 150 utilizes a frequency base value and a frequency increment that outputs a single value for a slope of a ramp that is used by an accumulator to generate a sine wave for the RF waveform. The sine wave is processed through an upconverter to generate the RF waveform signal to be applied to the magnetometry component, such as a DNV sensor. In some implementations, the CORDIC synthesis 150 may phase shift the RF waveform. For instance, an analog or digital switch may be used for arbitrary waveform generation. A more detailed implementation of the RF waveform generator and CORDIC synthesis 150 is shown as RF waveform generator 250 in FIGS. 2 and 3F.

The digital control 150 provides timing control for a number of aspects of a magnetometry component, such as a DNV sensor. The digital control 150 includes RF gating or switches and may include additional general inputs or outputs for additional control. The digital control 150 may output signals to control the activation of a magnetometry component, such as a laser for exciting a nitrogen vacancies of a DNV sensor. The digital control can also convert the CORDIC output to 0 via a multiplexer (MUX) such that no RF signal is applied to the DNV sensor. In some implementations, the digital control 150 can be used for an acousto-optic modulator (AOM) to control optic pulsing of the laser and/or can be used for phase shift control. The digital control 150 may further provide an output to an I/Q component, such as a digital I/Q. A more detailed implementation of the digital control 160 is shown as digital control 260 in FIGS. 2 and 3G.

The acquisition processor 180 provides initial synchronous preprocessing of data received from a magnetometry component, such as data received from a photo detector of a DNV sensor. The acquisition processor 180 can include two coherent channels for simultaneous collection of data, such as the collection of red light, infrared, laser, etc. data. In some implementations, the channels may be chainable up to four. In an implementation with a photo detector, data received by the acquisition processor 180 may be at a rate of 50 MHz, 100 MHz, 200 MHz, or greater. To reduce the amount of data transferred to an external system from the system 100, the acquisition processor can preprocess the data to reduce the size of the data outputted. Thus, in some implementations, the acquisition processor 180 synchronously gathers samples from a magnetometry component, such as the photo detector of a DNV sensor, and preprocesses the data, such as decimation of the data. In some implementations, the acquisition process 180 may include a digital output to trigger an accumulator for a predetermined number of clock cycles and then will subtract from two integration windows for processing of the data. By providing a consistent trigger based on a single-cycle of the system 100, the preprocessing of the acquired data can be more consistent, thereby increasing sensitivity and reducing noise in the acquired data from inconsistent triggers In some implementations, the acquisition processor 180 may include a digitally controllable offset for effects similar to a DC block or AC coupling. A more detailed implementation of the acquisition processor 180 is shown as acquisition processor 270 in FIGS. 2 and 3H.

In the implementation shown, the system 100 is configured for single-cycle instructions for the components of the system 100 such that the RF waveform generator of the CORDIC synthesis 150 for generating the RF waveform, the digital control 160 for controlling the laser on/off timing, and the acquisition processor 180 operate on the same clock cycle. A main counter (not shown) drives the RF waveform generation while the program counter 120 allows for delays to be implemented for the digital control 150 and the acquisition processor 180. The single-cycle can provide laser and/or microwave deterministic timing control for coordination of the CORDIC synthesis 150, the digital control 160, and the acquisition processor 180. Thus, the single-cycle tightly ties in the digital control 160 for controlling the laser and acquisition processor with the RF waveform generation of the CORDIC synthesis 150. The single-cycle permits synchronous stepped-frequency complex waveform synthesis by the CORDIC synthesis 150 and permits coordinated large-range frequency retuning (e.g., >1 GHz) without losing base time. The single-cycle system 100 can also provide synchronous reduced instruction set program control of the frequency for the RF waveform synthesis. The system 100 of FIG. 1 with a single-cycle also reduces redundant components compared to systems that utilize separate components for the RF waveform generator, digital control, and/or acquisition processor. In some implementations, the single-cycle synthesis, control, and acquisition system 100 may also be configured for two-cycle implementations as well.

The system 100 can utilize a reduced instruction set (RISC) engine that issues one instruction per clock cycle, including for conditional branching. In some implementations, the reduced instruction set can include commands for an unconditional jump (jmp), a conditional jump (cjmp), setting of a loop counter (setc <counter value>), setting of a frequency (setf <frequency value>), setting of a digital control output field (seto <output field value>), a frequency increment (incf <increment value>), and a delay for a specified cycle count (del <cycle count value>).

As a comprehensive system that exercises parameter variation, the single-cycle synthesis, control, and acquisition system 100 can provide lock-step precision for laser on/off timing via the digital control 160, sequenced microwave waveform synthesis and delivery via the RF waveform generator and CORDIC synthesis 150, data acquisition via the acquisition processor 170, and laser and/or microwave deterministic timing control. The single-cycle synthesis, control, and acquisition system 100 can facilitate effective experimentation by enabling rapid coordination of excitation signals and tuning across broad frequency ranges without losing timing. Not all of the depicted components may be required, however, and one or more implementations may include additional components not shown in the figure. Variations in the arrangement and type of the components may be made, and additional components, different components, or fewer components may be provided.

As noted above, FIG. 2 is a circuit diagram illustrating an example implementation of the single-cycle synthesis, control, and acquisition system 200. In one or more implementations, the single-cycle synthesis, control, and acquisition system 200, as implemented by the circuit of FIG. 2, is a dedicated hardware configured for DNV applications that are customized to the unique requirements of controlling multiple, diverse instruments and sensors across the RF to optical domain. The reduced instruction set (RISC) engine is configured to issue one instruction per clock cycle, even for conditional branches. The RF waveform generator uses a run-time configurable base frequency and increment to provide the CORDIC synthesis with an RF waveform for digital up/down conversion. The digital control block is responsible for providing laser timing, RF gating, and additional general control input/output (I/O). The acquisition processor block is configured to provide two coherent channels (potentially chainable up to 4) for simultaneous red, infra-red (IR), laser, and other types of light collection. The acquisition processing block is further configured to synchronously collect samples and to provide digitally controllable analog offset that allows effects like DC blocking or AC coupling.

Examples of advantageous features of the single-cycle synthesis, control, and acquisition system 200 include, but are not limited to, single-cycle deterministic timing coordination of RF waveform generation, laser control, and data acquisition, synchronous stepped-frequency for complex waveform synthesis, synchronous RISC program control of frequency, coordinated large-range (e.g., >1 GHz) frequency retuning without losing time base, and a minimal instruction set.

By providing a small-scale or single chip, single-cycle synthesis, control, and acquisition system 100, 200 for use in magnetometry, the system 100, 200 can be incorporated into a variety of settings and configurations where DNV magnetometers are employed. Examples of applications of the single-cycle synthesis, control, and acquisition system 100, 200 include, but are not limited to incorporating the single chip into a DNV sensor, incorporating the single chip into DNV-based geolocation systems, incorporating the single chip into DNV anomaly detection systems, incorporating the single chip into covert communications systems, incorporating the single chip into distributed measure point systems. incorporating the single chip into small form factor unmanned systems for air (e.g., unmanned air vehicle (UAV), micro unmanned air vehicle (μUAV), missiles), sea, underground, and surveillance (e.g., satellites, cluster satellites, etc.), incorporating the single chip into low SWAP (size, weight, and power) applications, and utilizing the single chip, single-cycle synthesis, control, and acquisition system 100, 200 for automatic experimental optimization.

FIG. 3 is a diagram illustrating an example of a system 300 for implementing some aspects of the subject technology. The system 300 includes a processing system 302, which may include one or more processors or one or more processing systems. A processor can be one or more processors. The processing system 302 may include a general-purpose processor or a specific-purpose processor for executing instructions and may further include a machine-readable medium 319, such as a volatile or non-volatile memory, for storing data and/or instructions for software programs. The instructions, which may be stored in a machine-readable medium 310 and/or 319, may be executed by the processing system 302 to control and manage access to the various networks, as well as provide other communication and processing functions. The instructions may also include instructions executed by the processing system 302 for various user interface devices, such as a display 312 and a keypad 314. The processing system 302 may include an input port 322 and an output port 324. Each of the input port 322 and the output port 324 may include one or more ports. The input port 322 and the output port 324 may be the same port (e.g., a bi-directional port) or may be different ports.

The processing system 302 may be implemented using software, hardware, or a combination of both. By way of example, the processing system 302 may be implemented with one or more processors. A processor may be a general-purpose microprocessor, a microcontroller, a Digital Signal Processor (DSP), an Application Specific Integrated Circuit (ASIC), a Field Programmable Gate Array (FPGA), a Programmable Logic Device (PLD), a controller, a state machine, gated logic, discrete hardware components, or any other suitable device that can perform calculations or other manipulations of information.

A machine-readable medium can be one or more machine-readable media. Software shall be construed broadly to mean instructions, data, or any combination thereof, whether referred to as software, firmware, middleware, microcode, hardware description language, or otherwise. Instructions may include code (e.g., in source code format, binary code format, executable code format, or any other suitable format of code).

Machine-readable media (e.g., 319) may include storage integrated into a processing system such as might be the case with an ASIC. Machine-readable media (e.g., 310) may also include storage external to a processing system, such as a Random Access Memory (RAM), a flash memory, a Read Only Memory (ROM), a Programmable Read-Only Memory (PROM), an Erasable PROM (EPROM), registers, a hard disk, a removable disk, a CD-ROM, a DVD, or any other suitable storage device. Those skilled in the art will recognize how best to implement the described functionality for the processing system 302. According to one aspect of the disclosure, a machine-readable medium is a computer-readable medium encoded or stored with instructions and is a computing element, which defines structural and functional interrelationships between the instructions and the rest of the system, which permit the instructions' functionality to be realized. Instructions may be executable, for example, by the processing system 302 or one or more processors. Instructions can be, for example, a computer program including code for performing methods of the subject technology.

A network interface 316 may be any type of interface to a network (e.g., an Internet network interface), and may reside between any of the components shown in FIG. 3 and coupled to the processor via the bus 304.

A device interface 318 may be any type of interface to a device and may reside between any of the components shown in FIG. 3. A device interface 318 may, for example, be an interface to an external device (e.g., USB device) that plugs into a port (e.g., USB port) of the system 300. In some implementations, the device interface 318 may be the host interface of FIG. 1, where at least some of the functionalities of the apparatus of FIG. 1 are performed by the processing system 302.

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology.

One or more of the above-described features and applications may be implemented as software processes that are specified as a set of instructions recorded on a computer readable storage medium (alternatively referred to as computer-readable media, machine-readable media, or machine-readable storage media). When these instructions are executed by one or more processing unit(s) (e.g., one or more processors, cores of processors, or other processing units), they cause the processing unit(s) to perform the actions indicated in the instructions. In one or more implementations, the computer readable media does not include carrier waves and electronic signals passing wirelessly or over wired connections, or any other ephemeral signals. For example, the computer readable media may be entirely restricted to tangible, physical objects that store information in a form that is readable by a computer. In one or more implementations, the computer readable media is non-transitory computer readable media, computer readable storage media, or non-transitory computer readable storage media.

In one or more implementations, a computer program product (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

While the above discussion primarily refers to microprocessor or multi-core processors that execute software, one or more implementations are performed by one or more integrated circuits, such as application specific integrated circuits (ASICs) or field programmable gate arrays (FPGAs). In one or more implementations, such integrated circuits execute instructions that are stored on the circuit itself.

In one or more implementations, the subject technology is directed to method and systems for providing precisely timed laser actuation, RF waveform control, and synchronous acquisition of fluorescence information from a DNV magnetometer. In some aspects, the subject technology may be used in various markets, including for example and without limitation, advanced sensors.

The description of the subject technology is provided to enable any person skilled in the art to practice the various embodiments described herein. While the subject technology has been particularly described with reference to the various figures and embodiments, it should be understood that these are for illustration purposes only and should not be taken as limiting the scope of the subject technology.

There may be many other ways to implement the subject technology. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made to the subject technology, by one having ordinary skill in the art, without departing from the scope of the subject technology.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A controller for a diamond nitrogen-vacancy (DNV) sensor comprising:
a RF waveform generator for generating a RF waveform for a RF signal for a DNV sensor; and
a digital control for controlling a laser for the DNV sensor;
wherein the RF waveform generator and the digital control are formed in a single chip.

2. The controller of claim 1, wherein the single chip is a field-programmable gate array.

3. The controller of claim 1, wherein the single chip is an application specific integrated circuit.

4. The controller of claim 1, wherein the RF waveform generator and the digital control operate on single-cycle instructions.

5. The controller of claim 1, wherein the RF waveform generator and the digital control operate on two-cycle instructions.

6. The controller of claim 1, wherein the RF waveform generator and the digital control operate on single-cycle instructions of a reduced instruction set.

7. The controller of claim 1, wherein the RF waveform generator includes a coordinate rotation digital computer.

8. The controller of claim 1, wherein the RF waveform generator utilizes a frequency base and a frequency increment to generate the RF waveform.

9. The controller of claim 1, wherein the RF waveform generated by the RF waveform generator is processed through an upconverter to generate the RF signal.

10. The controller of claim 1, wherein the digital control includes RF gating.

11. The controller of claim 1, wherein the digital control includes general inputs or outputs.

12. The controller of claim 1, wherein the digital control is configured to control the generation of the RF waveform.

13. The controller of claim 1, wherein the digital control is configured to control optic pulsing of the laser.

14. The controller of claim 1, wherein the single chip is configured to be integrated into one of:
a geo-location system,
an anomaly detection system,
a distributed measure point system,
a communication system,
an unmanned air vehicle,
a micro unmanned air vehicle,
a missile,
an unmanned sea vehicle,
an unmanned underground vehicle, or
a satellite.

15. A controller for a diamond nitrogen-vacancy (DNV) sensor comprising:
a RF waveform generator for generating a RF waveform for a RF signal for a DNV sensor;
a digital control for controlling a laser for the DNV sensor; and
an acquisition processor;
wherein the RF waveform generator, the digital control, and the acquisition processor are formed in a single chip.

16. The controller of claim 15, wherein the single chip is a field-programmable gate array.

17. The controller of claim 15, wherein the single chip is an application specific integrated circuit.

18. The controller of claim 15, wherein the RF waveform generator, the digital control, and the acquisition processor operate on single-cycle instructions.

19. The controller of claim 15, wherein the RF waveform generator, the digital control, and the acquisition processor operate on two-cycle instructions.

20. The controller of claim 15, wherein the RF waveform generator, the digital control, and the acquisition processor on single-cycle instructions of a reduced instruction set.

21. The controller of claim 15, wherein the acquisition processor preprocesses data received from a photo detector of the DNV sensor.

22. The controller of claim 16, wherein the acquisition processor decimates the data received from the photo detector of the DNV sensor.

23. The controller of claim 15, wherein the single chip is configured to be integrated into one of:
a geo-location system,
an anomaly detection system,
a distributed measure point system,
a communication system,
an unmanned air vehicle,
a micro unmanned air vehicle,
a missile,
an unmanned sea vehicle,
an unmanned underground vehicle, or
a satellite.

24. A controller for a diamond nitrogen-vacancy (DNV) sensor comprising:
a RF waveform generator for generating a RF waveform for a RF signal for a DNV sensor;
a digital control for controlling a laser for the DNV sensor;
an acquisition processor;
a host interface for interfacing with an external system;
a program counter;
a program memory; and
a jump control;
wherein the RF waveform generator, the digital control, the acquisition processor, the host interface, the program counter, the program memory, and the jump control are formed in a single chip.

25. The controller of claim 24, wherein the single chip is a field-programmable gate array.

26. The controller of claim 24, wherein the single chip is an application specific integrated circuit.

27. The controller of claim 24, wherein the RF waveform generator, the digital control, and the acquisition processor operate on single-cycle instructions.

28. The controller of claim 24, wherein the RF waveform generator, the digital control, and the acquisition processor operate on two-cycle instructions.

29. The controller of claim 24, wherein the RF waveform generator, the digital control, and the acquisition processor on single-cycle instructions of a reduced instruction set.

30. The controller of claim 24, wherein the single chip is configured to be integrated into one of:
a geo-location system,
an anomaly detection system,
a distributed measure point system,
a communication system,
an unmanned air vehicle,
a micro unmanned air vehicle,
a missile,
an unmanned sea vehicle,
an unmanned underground vehicle, or
a satellite.
